(19) United States
(12) Patent Application Publication
(10) Pub. No.: US 2026/0090221 A1
(43) Pub. Date: Mar. 26, 2026

(54) DISPLAY DEVICE

(71) Applicant: LG Display Co., Ltd., Seoul (KR)

(72) Inventors: Jinseong KIM, Paju-si (KR); Yongchan PARK, Paju-si (KR)

(73) Assignee: LG Display Co., Ltd., Seoul (KR)

(21) Appl. No.: 19/313,603

(22) Filed: Aug. 28, 2025

(30) Foreign Application Priority Data
Sep. 26, 2024 (KR) 10-2024-0130859

(51) Int. Cl. H10K 59/126; G09G 3/3233; H10K 59/123; H10K 59/131

(52) U.S. Cl. CPC H10K 59/126; G09G 3/3233; H10K 59/123; H10K 59/131; G09G 2300/0426; G09G 2300/0819; G09G 2300/0852; G09G 2300/0861

(57) ABSTRACT

A display device according to one embodiment includes a substrate including a display area and a non-display area adjacent to the display area. A first light-blocking layer is on the substrate. An active layer including a semiconductor area of a first transistor is on the first light-blocking layer, and a gate layer including a gate electrode of the first transistor is on the active layer. A source metal layer is on the gate layer and includes an anode connection electrode directly connected to the active layer to receive a driving current from the first transistor. A pixel electrode is on the source metal layer and directly connected to the anode connection electrode. A light-emitting layer is on the pixel electrode, and a common electrode is on the light-emitting layer. This structure supports efficient electrical connectivity and a simplified manufacturing process.

### CROSS REFERENCE TO RELATED APPLICATION

The present application claims priority to Korean Patent Application No. 10-2024-0130859, filed Sep. 26, 2024, the entire contents of which is incorporated herein for all purposes by this reference.

### BACKGROUND

### Technical Field

The present specification relates to a display device.

### Description of the Related Art

As the information society develops, various demands for display devices for displaying images are increasing, and various types of display devices such as liquid crystal display (LCD) devices and organic light emitting diode (OLED) display devices are utilized.

Images displayed on a display device may be still images or moving images, and the moving image may include various types such as sports images, game images, and movies. The display device may include a plurality of pixels, and a plurality of switching elements for driving the pixels.

### BRIEF SUMMARY

The display device according to various embodiments simplifies the manufacturing process and reduces costs by utilizing a source metal layer to connect the pixel circuit transistors to the pixel electrode, enabling vertical integration through contact holes formed using a mask. This structure eliminates the need for additional conductive layers while maintaining reliable electrical connectivity via an integrated anode connection electrode. Additionally, a capacitor is implemented using vertically stacked electrodes located in two separate light-blocking layers beneath the active layer, thereby enhancing driving stability and shielding the driving transistor from incident light.

Additionally, the device incorporates a layered voltage and signal routing architecture, with power, scan, and control lines distributed across different layers (light-blocking, gate, and source metal layers) to support compact and efficient layouts. A pad part formed in the light-blocking layer connects to an external flexible film (FPCB), and a fan-out line overlapping multiple voltage lines facilitates narrow bezel designs. Touch functionality is implemented above the encapsulation layers using stacked touch electrodes and insulating layers, enabling thin, integrated touch display configurations.

The present specification is directed to providing a display device in which it is possible to reduce the number of masks of a manufacturing process and reduce a manufacturing cost.

Technical benefits of the present specification are not limited to the above-described benefits, and other technical benefits may be inferred from the following embodiments.

According to one embodiment, there is provided a display device including a substrate including a display area and a non-display area surrounding the display area, a first light-blocking layer disposed on the substrate, an active layer including a semiconductor area of a first transistor disposed on the first light-blocking layer, a gate layer including a gate electrode of the first transistor disposed on the active layer, a source metal layer disposed on the gate layer and including an anode connection electrode that is directly connected to the active layer and receives a driving current flowing in the first transistor, a pixel electrode disposed on the source metal layer and directly connected to the anode connection electrode, a light-emitting layer disposed on the pixel electrode, and a common electrode disposed on the light-emitting layer.

According to another embodiment, there is provided a display device including a substrate including a display area and a non-display area surrounding the display area, a light-emitting element that includes a pixel electrode and emits light, a first transistor that supplies a driving current to the pixel electrode, an active layer disposed on the substrate and including a semiconductor area of the first transistor, a second transistor that supplies the data voltage to a gate electrode of the first transistor based on a first scan signal, a third transistor that supplies a reference voltage to the gate electrode of the first transistor based on a second scan signal, a fourth transistor that supplies a driving voltage to a drain electrode of the first transistor based on a first light-emitting signal, a fifth transistor including a drain electrode and a source electrode disposed in the active layer and electrically connecting the source electrode of the first transistor to the pixel electrode based on a second light-emitting signal, and an anode connection electrode directly connecting the source electrode of the fifth transistor to the pixel electrode.

Detailed matters of other embodiments are included in the detailed description and accompanying drawings.

### BRIEF DESCRIPTION OF THE SEVERAL VIEWS OF THE DRAWINGS

FIG. 1 is a block diagram illustrating a display device according to one embodiment.

FIG. 2 is a plan view illustrating a display device according to one embodiment.

FIG. 3 is a circuit diagram illustrating a circuit of the display device according to one embodiment.

FIG. 4 is a cross-sectional view illustrating the circuit of the display device according to one embodiment.

FIG. 5 is a plan view illustrating a voltage line in the display device according to one embodiment.

FIG. 6 is a cross-sectional view along line I-I′ in FIG. 5.

FIG. 7 is a cross-sectional view along line II-II′ in FIG. 5.

FIG. 8 is a cross-sectional view along line III-III′ in FIG. 5.

FIGS. 9 to 13 are cross-sectional views of a manufacturing process of the display device according to one embodiment.

### DETAILED DESCRIPTION

Hereinafter, embodiments will be described with reference to the accompanying drawings. In the specification, when a first component (or an area, a layer, a portion, etc.) is described as “on,” “connected,” or “coupled to” a second component, it means that the first component may be directly connected/coupled to the second component or a third component may be disposed therebetween.

To elaborate, as used herein, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

The same reference numerals indicate the same components. In addition, in the drawings, thicknesses, proportions, and dimensions of components are exaggerated for effective description of technical contents. The term “and/or” includes all one or more combinations that may be defined by the associated configurations.

Terms such as first and second may be used to describe various components, but the components are not limited by the terms. The terms are used only for the purpose of distinguishing one component from another. For example, a first component may be referred to as a second component, and similarly, the second component may also be referred to as the first component without departing from the scopes of the embodiments. The singular includes the plural unless the context clearly dictates otherwise.

Terms such as “under,” “at a lower side,” “above,” and “at an upper side” are used to describe the relationship between the components illustrated in the drawings. The terms are relative concepts and are described with respect to directions marked in the drawings.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

It should be understood that term such as “includes” or “has” is intended to specify the presence of features, numbers, steps, operations, components, parts, or a combination thereof described in the specification and does not preclude the presence or addition possibility of one or more other features, numbers, steps, operations, components, parts, or combinations thereof in advance.

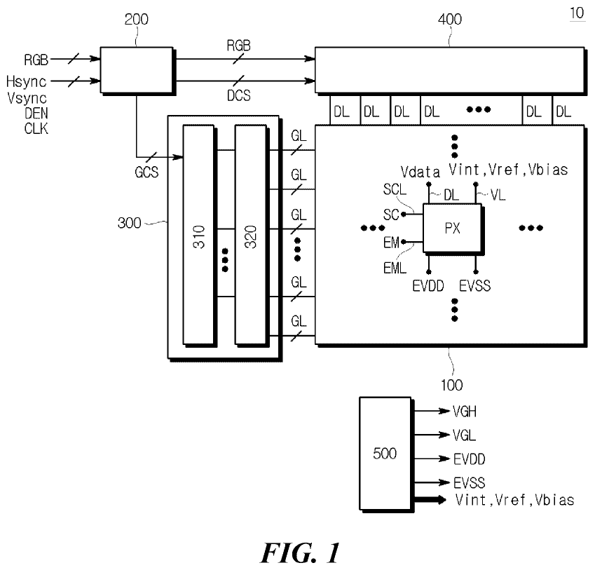

FIG. 1 is a block diagram illustrating a display device according to one embodiment.

Referring to FIG. 1, a display device 10 may be applied to portable electronic devices, such as a mobile phone, a smart phone, a tablet personal computer (PC), a mobile communication terminal, an electronic notebook, an electronic book, a portable multimedia player (PMP), a navigation device, an ultra-mobile PC (UMPC), etc. For example, the display device 10 may be applied to a television, a laptop, a monitor, a billboard, or a display unit of the Internet of Things (IOT). As another example, the display device 10 may be applied to a wearable device, such as a smart watch, a watch phone, a glasses-type display, and a head mounted display (HMD).

A display device 10 may include a display panel 100, a controller 200, a gate driver 300 that supplies gate signals to a plurality of pixels PX, a data driver 400 that supplies data voltages to the plurality of pixels PX, and a power supply unit 500 that supplies power to the plurality of pixels PX.

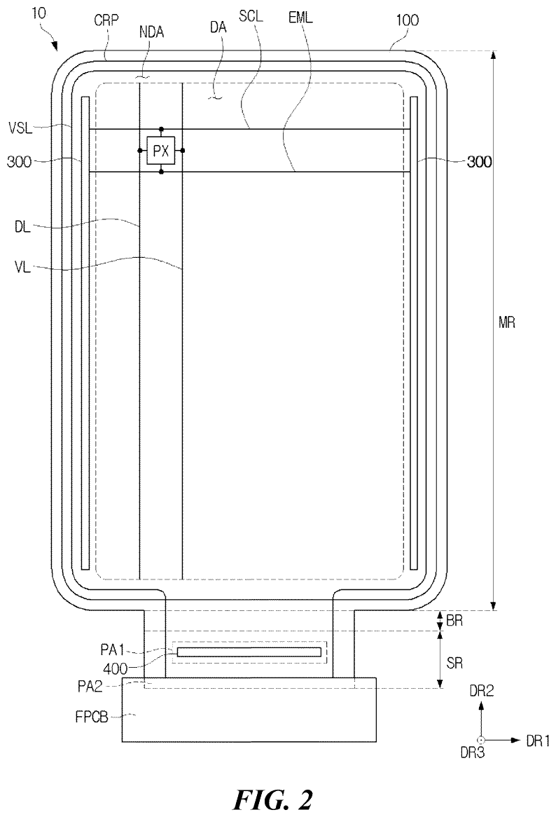

The display panel 100 may include a display area DA (see FIG. 2) and a non-display area NDA (see FIG. 2). The display area DA may include the plurality of pixels PX. The non-display area NDA may surround the display area DA and include the gate driver 300 and the data driver 400.

A plurality of gate lines GL and a plurality of data lines DL may intersect each other in the display panel 100 and may be electrically connected to each of the pixels PX. For example, one pixel PX may receive the gate signal from the gate driver 300 through the gate line GL, receive the data signal from the data driver 400 through the data line DL, and receive a driving voltage EVDD and a low-potential voltage EVSS from the power supply unit 500.

The gate line GL may include a scan line SCL and a light-emitting control line EML. The scan line SCL may supply a scan signal SC to the pixels PX, and the light-emitting control line EML may supply a light-emitting control signal EM to the pixels PX. The data line DL may supply a data voltage Vdata to the pixels PX, and a power line VL may supply a power voltage. Here, the power voltage may include the driving voltage EVDD, the low-potential voltage EVSS, an initialization voltage Vint, a reference voltage Vref, and a bias voltage Vbias, but is not limited thereto.

The display panel 100 may include a non-transmissive display panel or a transmissive display panel. The transmissive display panel may display an image on a screen and may be applied to a transparent display device in which an actual background is visible. For example, the display panel 100 may be implemented as a flexible display panel including a plastic substrate.

Touch sensors may be disposed on the display panel 100. A touch input may be sensed using separate touch sensors or sensed through the pixels PX. The touch sensors are on-cell type or add-on type touch sensors and may be implemented as an in-cell type touch sensors disposed on the screen of the display panel 100 or embedded into the display panel 100.

The controller 200 may process image data RGB input from a host system (not illustrated) to be suitable for the size and resolution of the display panel 100 and supply the processed image data RGB to the data driver 400. Here, the host system may be one of a TV system, a set-top box, a navigation system, a personal computer (PC), a home theater system, a mobile device, a wearable device, and a vehicle system. The controller 200 may generate a gate control signal GCS and a data control signal DCS based on synchronous signals input from the host system. Here, the synchronous signals may include a clock signal CLK, a data enable signal DEN, a horizontal synchronous signal Hsync, and a vertical synchronous signal Vsync, but are not limited thereto. The gate control signal GCS may be supplied to the gate driver 300 to control the operation timing of the gate driver 300, and the data control signal DCS may be supplied to the data driver 400 to control the operation timing of the data driver 400. For example, the controller 200 may be configured in combination with a microprocessor, a mobile processor, an application processor, etc.

The controller 200 may drive the pixels PX at various refresh rates. The controller 200 may drive the pixels PX in a variable refresh rate (VRR) mode or drive the pixels PX to be switchable between a first refresh rate and a second refresh rate. For example, the controller 200 may drive the pixel PX at various refresh rates by simply changing rates of clock signals, generating synchronization signals to generate a horizontal blank or a vertical blank, or driving the gate driver 300 in a mask manner.

The gate control signal GCS may be converted into voltage levels of a gate high voltage VGH and a gate low voltage VGL through a level shifter (not illustrated) and supplied to the gate driver 300. The level shifter may convert the high level voltage of the gate control signal GCS into the gate high voltage VGH and the low level voltage of the gate control signal GCS into the gate low voltage VGL. The gate control signal GCS may include a start pulse and a shift clock.

The gate driver 300 may supply the gate signal to the gate line GL based on the gate control signal GCS supplied from the controller 200. The gate driver 300 may include a scan driver 310 and a light-emitting control driver 320. The gate line GL may include the scan line SCL and the light-emitting control line EML. The scan driver 310 may supply the scan signal SC to the scan line SCL, and the light-emitting control driver 320 may supply the light-emitting control signal EM to the light-emitting control line EML. Each of the scan signal SC and the light-emitting control signal EM may include a pulse that swings between the gate high voltage VGH and the gate low voltage VGL. The scan signal SC may select the pixels PX of a line on which data is written in synchronization with the data voltage Vdata, and the light-emitting control signal EM may define light-emitting times of the pixels PX. The gate driver 300 may be disposed on one side or both sides of the display panel 100 in a gate in panel (GIP) manner. The gate driver 300 may shift the gate signals using the shift register and sequentially supply the shifted gate signals to the gate lines GL.

The data driver 400 may convert the image data RGB into the data voltage Vdata according to the data control signal DCS supplied from the controller 200 and supply the converted data voltage Vdata to the data lines DL. The number and arrangement location of the data driver 400 are not limited to those illustrated in FIG. 1. For example, the data driver 400 may be composed of a plurality of integrated circuits (ICs) and disposed separately as a plurality of data drivers on one side of the display panel 100.

The power supply unit 500 may generate DC power required for driving the display panel 100 using a DC-DC converter. For example, the DC-DC converter may include a charge pump, a regulator, a buck converter, a boost converter, etc. The power supply unit 500 may receive a DC input voltage applied from the host system and generate a DC voltage, such as the gate high voltage VGH, the gate low voltage VGL, the driving voltage EVDD, the low-potential voltage EVSS, the initialization voltage Vint, the reference voltage Vref, and the bias voltage Vbias. The gate high voltage VGH and the gate low voltage VGL may be supplied to the level shifter and the gate driver 300. The driving voltage EVDD, the low-potential voltage EVSS, the initialization voltage Vint, and the reference voltage Vref may be supplied to the pixels PX.

FIG. 2 is a plan view illustrating a display device according to one embodiment.

Referring to FIG. 2, the display panel 100 may include the display area (DA) and the non-display area NDA. The flat surface shape of the display area DA may have a rectangular shape. The display area DA may have a rectangular shape with rounded corners, but is not limited thereto. As another example, the flat surface shape of the display area DA may be a square, a circle, an oval, or other polygonal shapes.

Hereinafter, a first direction DR1 and a second direction DR2 are mutually intersecting directions and represent directions that intersect vertically in a plan view. The first direction DR1 may be generally the same as an extension direction of short sides of the display panel 100, and the second direction DR2 may be the same as an extension direction of long sides of the display panel 100. However, the directions described in the embodiments should be understood as indicating relative directions, and the embodiments are not limited to the described directions.

The display area DA may include short sides extending in the first direction DR1 and long sides extending in the second direction DR2. The non-display area NDA may surround the display area DA. The non-display area NDA may include a first side disposed in the first direction DR1 of the display area DA, a second side disposed in a direction opposite to the first direction DR1, a third side disposed in the second direction DR2, and a fourth side disposed in a direction opposite to the second direction DR2. Here, in the non-display area NDA, the first side may be a right side, the second side may be a left side, the third side may be an upper side, and the fourth side may be a lower side.

The scan lines SCL may extend in the first direction DR1 and may be spaced apart from each other in the second direction DR2. The scan lines SCL may sequentially supply the scan signal SC to the plurality of pixels PX.

The light-emitting control lines EML may extend in the first direction DR1 and may be spaced apart from each other in the second direction DR2. The light-emitting control lines EML may sequentially supply the light-emitting signal EM to the plurality of pixels PX.

The data lines DL may extend in the second direction DR2 and may be spaced apart from each other in the first direction DR1. The data lines DL may supply the data voltages to the pixels PX. The data voltages may determine the luminance of each of the pixels PX.

The power lines VL may extend in the second direction DR2 and may be spaced apart from each other in the first direction DR1. The power lines VL may supply the power voltages to the pixels PX. Here, the power voltage may include the driving voltage EVDD, the low-potential voltage EVSS, an initialization voltage Vint, a reference voltage Vref, and a bias voltage Vbias, but is not limited thereto.

The gate driver 300 may be disposed at each of the first side and the second side of the non-display area NDA. A low-potential line VSL may be disposed in the non-display area NDA to surround the gate driver 300 and the display area DA. For example, the low-potential line VSL may extend from a flexible film FPCB and pass through a sub-region SR and a bending region BR and may be disposed on the first to fourth sides of the non-display area NDA to surround the gate driver 300 and the display area DA.

The display panel 100 may include the main region MR, the bending region BR, and the sub-region SR. The main region MR may include the display area DA and the non-display area NDA. The bending region BR may be disposed between the main region MR and the sub-region SR. The bending region BR may extend from the fourth side of the non-display region NDA in the direction opposite to the second direction DR2. The sub-region SR may extend from the bending region BR in the direction opposite to the second direction DR2.

The sub-region SR may include a first pad area PA1 and a second pad area PA2. The first pad area PA1 may be disposed in a central portion of the sub-region SR and connected to the data driver 400. The second pad area PA2 may be disposed at an end of the sub-region SR and connected to the flexible film FPCB.

The data driver 400 may be formed in the form of an integrated circuit (IC). For example, the data driver 400 may be disposed in a chip on plastic (CIP) manner in which the data driver 400 is directly mounted on the display panel 100. As another example, the data driver 400 may be disposed in a chip on glass manner or a chip on film manner.

The display panel 100 may further include a crack sensing pattern CRP surrounding the low-potential line VSL. The crack sensing pattern CRP may be disposed on the first to fourth sides of the non-display area NDA to completely surround the display area DA. As another example, the crack sensing pattern CRP may not be disposed on a part of the non-display area NDA.

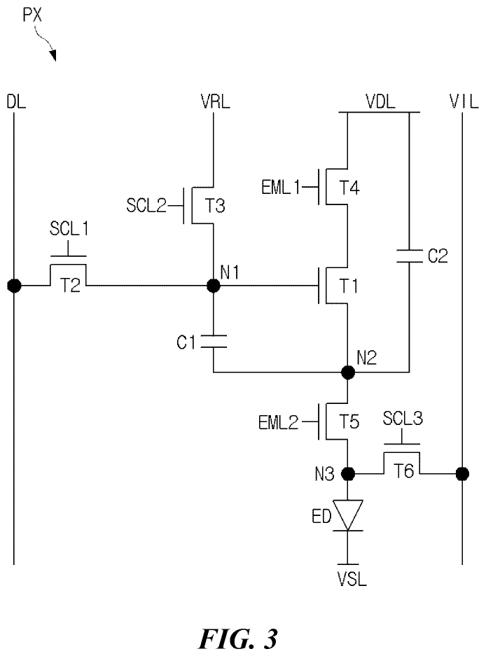

FIG. 3 is a circuit diagram illustrating a circuit of the display device according to one embodiment.

Referring to FIG. 3, each of the plurality of pixels PX may be connected to a first scan line SCL1, a second scan line SCL2, a third scan line SCL3, a first light-emitting control line EML1, a second light-emitting control line EML2, the data line DL, a reference voltage line VRL, a driving voltage line VDL, an initialization voltage line VIL, and the low-voltage line VSL.

The pixel PX may include a pixel circuit and a light-emitting element ED. The pixel circuit may include a first transistor T1, a second transistor T2, a third transistor T3, a fourth transistor T4, a fifth transistor T5, a sixth transistor T6, a first capacitor C1, and a second capacitor C2.

The first transistor T1 may include a gate electrode, a drain electrode, and a source electrode. The first transistor T1 may control a drain-source current (Ids) (or a driving current) according to the data voltage applied to the gate electrode. The driving current (Ids) flowing through a channel of the first transistor T1 may be proportional to the square of a difference between a voltage (Vgs) between the gate electrode and the source electrode of the first transistor T1 and a threshold voltage (Vth) of the first transistor T1(Ids=k×(Vgs−Vth)²). Here, k denotes a proportional coefficient determined by the structure and physical characteristics of the first transistor T1, Vgs denotes a gate-source voltage of the first transistor T1, and Vth denotes the threshold voltage of the first transistor T1. The gate electrode of the first transistor T1 may be electrically connected to a first node N1, the drain electrode may be connected to a source electrode of the fourth transistor T4, and the source electrode may be electrically connected to a second node N2.

The light-emitting element ED may receive the driving current (Ids) and emit light. The amount of light emitted or the luminance of the light-emitting element ED may be proportional to the magnitude of the driving current (Ids). The light-emitting element ED may be an organic light-emitting diode including a first electrode, a second electrode, and an organic light-emitting layer disposed between the first electrode and the second electrode, but the type of the light-emitting element ED is not limited thereto.

The first electrode of the light emitting element ED may be electrically connected to a third node N3. The first electrode of the light-emitting element ED may be connected to a source electrode of a fifth transistor T5 and a drain electrode of a sixth transistor T6 via the third node N3. Here, the first electrode of the light-emitting element ED may be an anode electrode or a pixel electrode. The second electrode of the light-emitting element ED may be electrically connected to the low-potential line VSL and may receive the low-potential voltage EVSS from the low-potential line VSL. Here, the second electrode of the light-emitting element ED may be a cathode electrode or a common electrode.

The second transistor T2 may be turned on by a first scan signal of the first scan line SCL1 to electrically connect the data line DL to the first node N1, which is the gate electrode of the first transistor T1. The second transistor T2 may be turned on based on the first scan signal to supply the data voltage to the first node N1. In the second transistor T2, a gate electrode may be electrically connected to the first scan line SCL1, a drain electrode may be electrically connected to the data line DL, and a source electrode may be electrically connected to the first node N1.

The third transistor T3 may be turned on by a second scan signal of the second scan line SCL2 to electrically connect the reference voltage line VRL to the first node N1, which is the gate electrode of the first transistor T1. The third transistor T3 may be turned on based on the second scan signal to supply the reference voltage Vref to the first node N1. In the third transistor T3, a gate electrode may be electrically connected to the second scan line SCL2, a drain electrode may be electrically connected to the reference voltage line VRL, and a source electrode may be electrically connected to the first node N1.

The fourth transistor T4 may be turned on by a first light-emitting signal of the first light-emitting control line EML1 to electrically connect the driving voltage line VDL to the drain electrode of the first transistor T1. In the fourth transistor T4, a gate electrode may be electrically connected to the first light-emitting control line EML1, a drain electrode may be electrically connected to the driving voltage line VDL, and a source electrode may be electrically connected to the drain electrode of the first transistor T1.

The fifth transistor T5 may be turned on by a second light-emitting signal of the second light-emitting control line EML2 to electrically connect the second node N2 to the third node N3. In the fifth transistor T5, a gate electrode may be electrically connected to the second light-emitting control line EML2, a drain electrode may be electrically connected to the second node N2, and a source electrode may be electrically connected to the third node N3.

The sixth transistor T6 may be turned on by a third scan signal of the third scan line SCL3 to electrically connect the third node N3, which is the first electrode of the light-emitting element ED, to the initialization voltage line VIL. The sixth transistor T6 may be turned on based on the third scan signal to initialize the first electrode of the light-emitting element ED with the initialization voltage. In the sixth transistor T6, a gate electrode may be electrically connected to the third scan line SCL3, a drain electrode may be electrically connected to the third node N3, and a source electrode may be electrically connected to the initialization voltage line VIL.

The first to sixth transistors T1, T2, T3, T4, T5, and T6 may include an oxide-based active layer. The first to sixth transistors T1, T2, T3, T4, T5, and T6 may correspond to n-type transistors and output a current flowing into the drain electrode to the source electrode based on the gate high voltage VGH applied to the gate electrode. The oxide-based active layer may have a relatively small S-factor, increase a constant current driving area in a low-gray area, and improve low-gray representation.

As another example, at least one of the first to sixth transistors T1, T2, T3, T4, T5, and T6 may include an active layer formed of low-temperature polycrystalline silicon (LTPS). At least one of the first to sixth transistors T1, T2, T3, T4, T5, and T6 may correspond to a p-type transistor and output a current flowing into the source electrode to the drain electrode based on the gate low voltage VGL applied to the gate electrode.

The first capacitor C1 may be electrically connected between the first node N1, which is the gate electrode of the first transistor T1, and the second node N2, which is the source electrode of the first transistor T1. For example, a first capacitor electrode of the first capacitor C1 may be electrically connected to the first node N1, and a second capacitor electrode of the first capacitor C1 may be electrically connected to the second node N2, thereby maintaining a potential difference between the gate electrode and the source electrode of the first transistor T1.

The second capacitor C2 may be electrically connected between the driving voltage line VDL and the second node N2, which is the source electrode of the first transistor T1. For example, a first capacitor electrode of the second capacitor C2 may be electrically connected to the driving voltage line VDL, and a second capacitor electrode of the second capacitor C2 may be electrically connected to the second node N2, thereby maintaining a potential difference between the driving voltage line VDL and the source electrode of the first transistor T1.

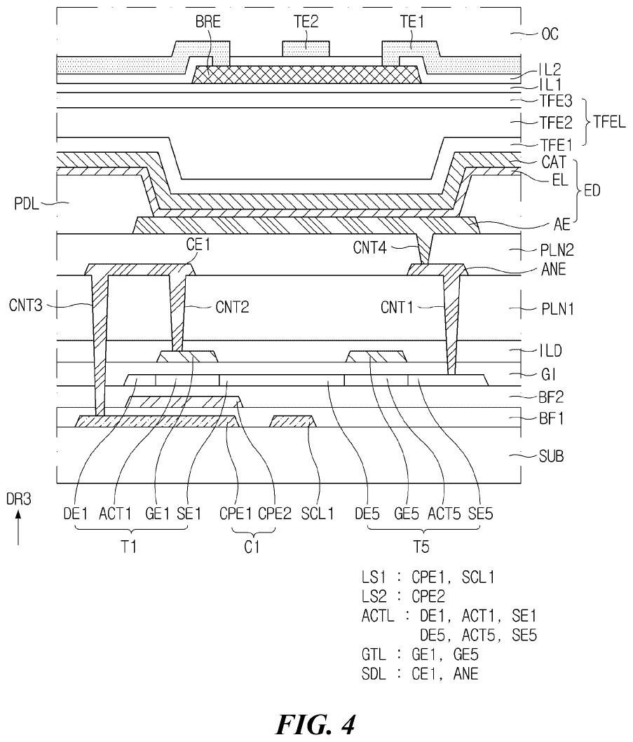

FIG. 4 is a cross-sectional view illustrating the circuit of the display device according to one embodiment.

Referring to FIG. 4, the display panel 100 may include a substrate SUB, a first light-blocking layer LS1, a first buffer layer BF1, a second light-blocking layer LS2, a second buffer layer BF2, an active layer ACTL, a gate insulating layer GI, a gate layer GTL, an interlayer insulating layer ILD, a first protective layer PLN1, a source metal layer SDL, a second protective layer PLN2, a light-emitting element ED, a pixel defining layer PDL, an encapsulation layer TFEL, a first insulating layer IL1, a bridge electrode BRE, a second insulating layer IL2, a first touch electrode TE1, a second touch electrode TE2, and a planarization layer OC.

The substrate SUB may be a base substrate or a base member. The substrate SUB may include at least one plastic material. For example, the substrate SUB may be a multi-substrate including a plurality of plastic materials, such as polyimide, but a constituent material of the substrate SUB is not limited thereto.

The first light-blocking layer LS1 may be disposed on the substrate SUB. The first light-blocking layer LS1 may include a first capacitor electrode CPE1 of the first capacitor C1 and the first scan line SCL1. The first capacitor electrode CPE1 may be disposed below the first transistor T1 to block light incident on the first transistor T1. The first capacitor electrode CPE1 may overlap a second capacitor electrode CPE2 to form the first capacitor C1. The first scan line SCL1 may supply the first scan signal to the second transistor T2 illustrated in FIG. 3. The first light-blocking layer LS1 may be formed of a single layer or multiple layers formed of one of molybdenum (Mo), aluminum (Al), chromium (Cr), gold (Au), titanium (Ti), nickel (Ni), neodymium (Nd), and copper (Cu), or an alloy thereof, but is not limited thereto.

The first buffer layer BF1 may be disposed on the first light-blocking layer LS1. The first buffer layer BF1 may include an inorganic film capable of preventing the penetration of air or moisture. For example, the first buffer layer BF1 may include a plurality of inorganic films alternately stacked.

The second light-blocking layer LS2 may be disposed on the first buffer layer BF1. The second light-blocking layer LS2 may include the second capacitor electrode CPE2 of the first capacitor C1. The second capacitor electrode CPE2 may be disposed below the first transistor T1 to block light incident on the first transistor T1. The second capacitor electrode CPE2 may overlap the first capacitor electrode CPE1 to form the first capacitor C1. The second light-blocking layer LS2 may include a material exemplified in the first light-blocking layer LS1, but is not limited thereto.

The second buffer layer BF2 may be disposed on the second light-blocking layer LS2. The second buffer layer BF2 may include an inorganic film capable of preventing the penetration of air or moisture. For example, the second buffer layer BF2 may include a plurality of inorganic films alternately stacked.

The active layer ACTL may be disposed on the second buffer layer BF2. The active layer ACTL may include an oxide-based material, but is not limited thereto. The active layer ACTL may include a semiconductor area ACT1, a drain electrode DE1, a source electrode SEI of the first transistor T1, and a semiconductor area ACT5, a drain electrode DE5, and a source electrode SE5 of the fifth transistor T5.

The gate insulating layer GI may be disposed on the active layer ACTL. The gate insulating layer GI may insulate an active layer ACTL1 and the gate layer GTL.

The gate layer GTL may be disposed on the gate insulating layer GI. The gate layer GTL may include a gate electrode GE1 of the first transistor T1 and a gate electrode GE5 of the fifth transistor T5. The gate electrode GE5 of the fifth transistor T5 may be a part of the second light-emitting control line EML2 illustrated in FIG. 3.

The interlayer insulating layer ILD may be disposed on the gate layer GTL. The interlayer insulating layer ILD may insulate the gate layer GTL and the source metal layer SDL.

The first protective layer PLN1 may be disposed on the interlayer insulating layer ILD. The first protective layer PLN1 may planarize upper portions of the transistors and protect the transistors. The first protective layer PLN1 may include an organic material. For example, the first protective layer PLN1 may include an acrylic resin, an epoxy resin, a phenolic resin, a polyamide resin, or a polyimide resin, but is not limited thereto.

The source metal layer SDL may be disposed on the first protective layer PLN1. The source metal layer SDL may include the first connection electrode CE1 and an anode connection electrode ANE. The first connection electrode CE1 may electrically connect the gate electrode GE1 of the first transistor T1 and the first capacitor electrode CPE1 of the first capacitor C1. The first connection electrode CE1 may be inserted into a second contact hole CNT2 passing through the first protective layer PLN1 and the interlayer insulating layer ILD to be in contact with the gate electrode GE1 of the first transistor T1. The first connection electrode CE1 may be inserted into a third contact hole CNT3 passing through the first protective layer PLN1, the interlayer insulating layer ILD, the gate insulating layer GI, the second buffer layer BF2, and the first buffer layer BF1 to be in contact with the first capacitor electrode CPE1.

The anode connection electrode ANE may electrically connect the source electrode SE5 to a pixel electrode unforE of the fifth transistor T5. The anode connection electrode ANE may be inserted into the first contact hole CNT1 passing through the first protective layer PLN1, the interlayer insulating layer ILD, and the gate insulating layer GI to be in contact with the source electrode SE5 of the fifth transistor T5.

The second protective layer PLN2 may be disposed on the source metal layer SDL. The second protective layer PLN2 may planarize an upper portion of the source metal layer SDL and protect the source metal layer SDL. The second protective layer PLN2 may include an organic material. For example, the second protective layer PLN2 may include the material exemplified in the first protective layer PLN1, but is not limited thereto.

The pixel defining layer PDL may be disposed on the second protective layer PLN2. The pixel defining layer PDL may define a light-emitting area or an opening area. The pixel defining layer PDL may include a material including a black pigment, etc., an organic material, such as a benzocyclobutene resin, a polyimide resin, an acrylic resin, a photosensitive polymer, etc., but is not limited thereto. When the pixel defining layer PDL includes a material including a black pigment, a black dye, etc., the pixel defining layer PDL may be a black bank. The pixel defining layer PDL may include a black pigment or a black dye, thereby blocking external light and increasing the luminance of the display device 10.

Optionally, a spacer (not illustrated) may be disposed on the pixel defining layer PDL. The spacer may include the same material as the pixel defining layer PDL, but is not limited thereto.

The light-emitting element ED may include a pixel electrode AE, a light-emitting layer EL, and a common electrode CAT. The pixel electrode AE may be disposed on the second protective layer PLN2. The pixel electrode AE may overlap one of a plurality of light-emitting areas defined by the pixel defining layer PDL. The pixel electrode AE may receive a driving current from a pixel circuit of the pixel PX. The pixel electrode AE may be a first electrode of the light-emitting element ED of FIG. 3.

The light-emitting layer EL may be disposed on the pixel electrode AE. For example, the light-emitting layer EL may be an organic light-emitting layer formed of an organic material, but is not limited thereto.

The common electrode CAT may be disposed on the light-emitting layer EL. For example, the common electrode CAT may be implemented in the form of an electrode that is common to all pixels PX without being distinguished by each pixel PX. The common electrode CAT may be a transparent electrode and may transmit light. The common electrode CAT may be electrically connected to the low-potential line VSL and may receive a low-potential voltage, a common voltage, or a cathode voltage. The common electrode CAT may be a second electrode of the light-emitting element ED of FIG. 3.

When the light-emitting layer EL corresponds to an organic light-emitting layer, when the pixel circuit of the pixel PX applies a predetermined voltage to the pixel electrode AE and the common electrode CAT receives the common voltage or the cathode voltage, holes may move to the light-emitting layer EL through the hole transporting layer, electrons may move to the light-emitting layer EL through the electron transporting layer, and the holes and electrons may be combined in the light-emitting layer EL to emit light.

The encapsulation layer TFEL may be disposed on the light-emitting element ED. The encapsulation layer TFEL may be disposed on the common electrode CAT to cover a plurality of light-emitting elements ED. The encapsulation layer TFEL may include a first encapsulation layer TFE1, a second encapsulation layer TFE2, and a third encapsulation layer TFE3 sequentially stacked on the common electrode CAT.

The first encapsulation layer TFE1 may be disposed on the common electrode CAT. The first encapsulation layer TFE1 may include an inorganic material to prevent oxygen or moisture from penetrating the light-emitting element ED. For example, the first encapsulation layer TFE1 may include at least one of a silicon nitride layer, a silicon oxynitride layer, a silicon oxide layer, a titanium oxide layer, an aluminum oxide layer, and an amorphous silicon layer, but is not limited thereto.

The second encapsulation layer TFE2 may be disposed on the first encapsulation layer TFE1 to planarize upper ends of the plurality of light-emitting elements ED. The second encapsulation layer TFE2 may include an organic material to protect the light-emitting element ED from foreign substances, such as dust. For example, the second encapsulation layer TFE2 may include an organic film, such as an acrylic resin, an epoxy resin, a phenolic resin, a polyamide resin, a polyimide resin, etc. The second encapsulation layer TFE2 may be formed by curing a monomer or coating a polymer.

The third encapsulation layer TFE3 may be disposed on the second encapsulation layer TFE2. The third encapsulation layer TFE3 may include an inorganic material to prevent oxygen or moisture from penetrating the light-emitting element ED. For example, the third encapsulation layer TFE3 may include the material exemplified in the first encapsulation layer TFE1, but is not limited thereto.

The first insulating layer IL1 may be disposed on the encapsulation layer TFEL. The first insulating layer IL1 may have an insulating and optical function. The first insulating layer IL1 may include at least one inorganic film.

The bridge electrode BRE may be disposed on the first insulating layer IL1. The bridge electrode BRE may be disposed on a different layer from the first and second touch electrodes TE1 and TE2 to electrically connect the first touch electrodes TE1 spaced apart from each other with the second touch electrode TE2 interposed therebetween.

The second insulating layer IL2 may be disposed on the bridge electrode BRE. The second insulating layer IL2 may insulate the bridge electrode BRE and the first and second touch electrodes TE1 and TE2. The second insulating layer IL2 may include at least one inorganic film.

The first touch electrode TE1 and the second touch electrode TE2 may be disposed on the second insulating layer IL2. The first and second touch electrodes TE1 and TE2 may be formed of a single layer of molybdenum (Mo), titanium (Ti), copper (Cu), aluminum (Al), and indium tin oxide (ITO) or formed of a stacked structure of aluminum and titanium (Ti/Al/Ti), a stacked structure of aluminum and ITO (ITO/AI/ITO), an APC alloy, and a stacked structure of APC alloy and ITO (ITO/APC/ITO).

The planarization layer OC may be disposed on the first and second touch electrodes TE1 and TE2. The planarization layer OC may planarize upper portions of the first and second touch electrodes TE1 and TE2 and protect the first and second touch electrodes TE1 and TE2. The planarization layer OC may include an organic insulation material.

The display device 10 may include only one source metal layer SDL between the transistors of the pixel circuit and the pixel electrode AE of the light-emitting element ED, thereby reducing the number of masks in the manufacturing process and the manufacturing cost. The display device 10 may reduce the number of conductive layers, thereby optimizing the process and shortening the manufacturing period.

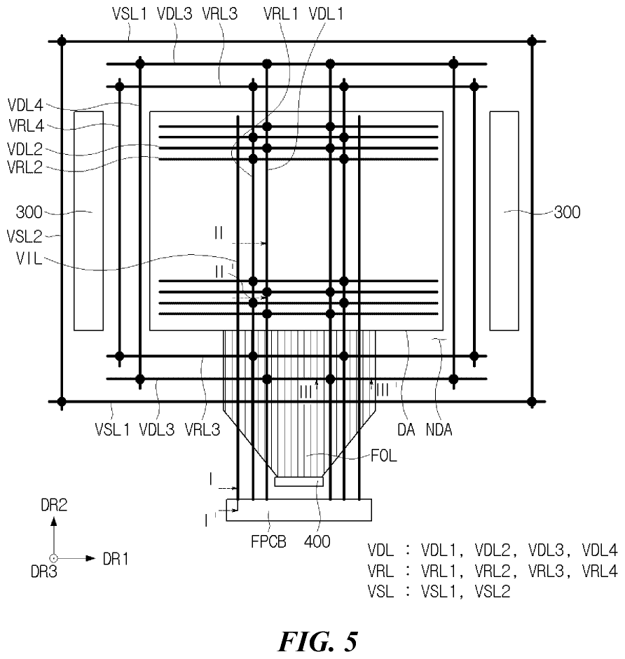

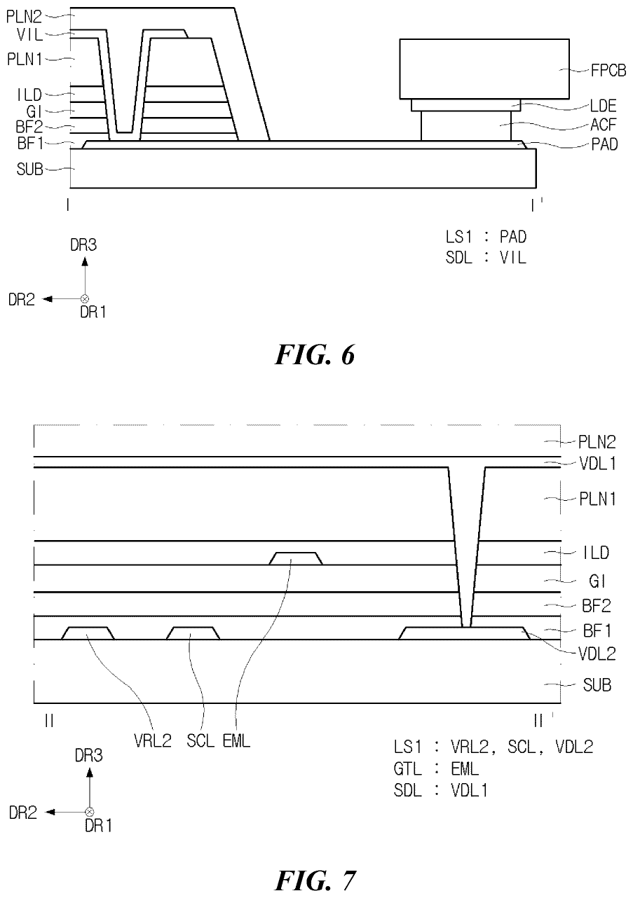

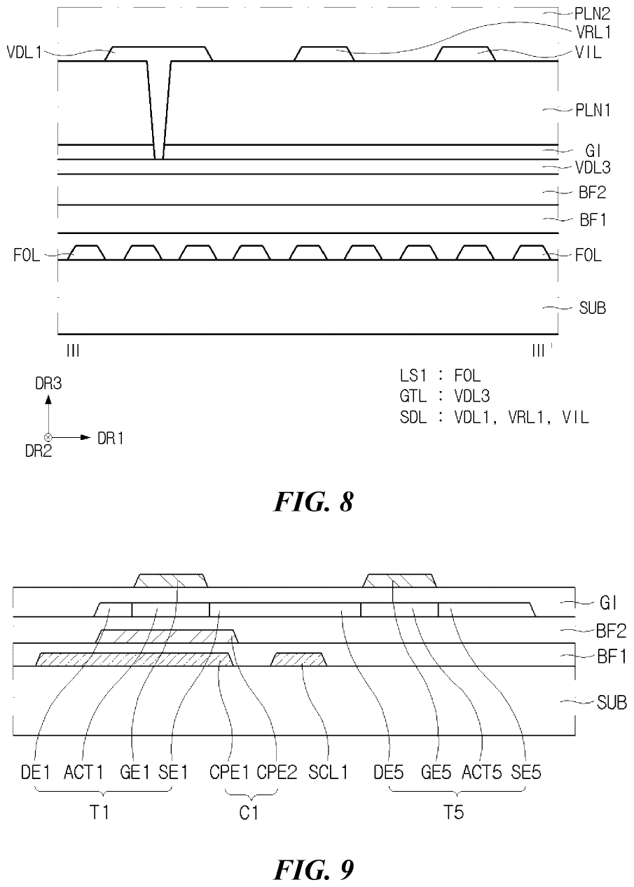

FIG. 5 is a plan view illustrating a voltage line in the display device according to one embodiment. FIG. 6 is a cross-sectional view along line I-I′ in FIG. 5, FIG. 7 is a cross-sectional view along line II-II′ in FIG. 5, and FIG. 8 is a cross-sectional view along line III-III′ in FIG. 5. Among the descriptions of the cross-sectional views of FIGS. 6 to 8, the configuration described above in the cross-sectional view of FIG. 4 will be briefly described or omitted.

Referring to FIGS. 5 to 8, the flexible film FPCB may be electrically connected to the display panel 100 through the second pad area PA2 illustrated in FIG. 2. The flexible film FPCB may supply the driving voltage EVDD to the driving voltage line VDL, the reference voltage Vref to the reference voltage line VRL, and the initialization voltage Vint to the initialization voltage line VIL.

The driving voltage line VDL may include first to fourth driving voltage lines VDL1, VDL2, VDL3, and VDL4. In FIGS. 5 and 7, the first driving voltage line VDL1 may extend from the source metal layer SDL in the second direction DR2. The first driving voltage line VDL1 may extend from a lower side of the non-display area NDA to an upper side of the display area DA. The first driving voltage line VDL1 may supply the driving voltage EVDD received from the flexible film FPCB to the display area DA. The first driving voltage line VDL1 may overlap a fan out line FOL on the lower side of the non-display area NDA and intersect a third driving voltage line VDL3, a third reference voltage line VRL3, and the first low-potential line VSL1. The first driving voltage line VDL1 may intersect a second driving voltage line VDL2 and a second reference voltage line VRL2 in the display area DA. The first driving voltage line VDL1 may intersect the third driving voltage line VDL3 and the third reference voltage line VRL3 on the upper side of the non-display area NDA.

In FIGS. 5 and 7, the second driving voltage line VDL2 may extend from the first light-blocking layer LS1 in the first direction DR1. The second driving voltage line VDL2 may extend from the left side to the right side of the display area DA. The second driving voltage line VDL2 may be connected to the first driving voltage line VDL1 to receive the driving voltage EVDD and supply the driving voltage EVDD to the pixel PX.

In FIGS. 5 and 8, the third driving voltage line VDL3 may extend from the gate layer GTL in the first direction DR1. The third driving voltage line VDL3 may be disposed on each of the upper and lower sides of the non-display area NDA. The third driving voltage line VDL3 may intersect the fan out line FOL, the first driving voltage line VDL1, the first reference voltage line VRL1, and the initialization voltage line VIL on the lower side of the non-display area NDA. The third driving voltage line VDL3 may be connected to the first driving voltage line VDL1 to receive the driving voltage EVDD and supply the driving voltage EVDD to the fourth driving voltage line VDL4.

The fourth driving voltage line VDL4 may extend from each of the left and right sides of the non-display area NDA in the second direction DR2. The fourth driving voltage line VDL4 may be disposed between the gate driver 300 and the display area DA. Although not illustrated, the fourth driving voltage line VDL4 may be disposed in the source metal layer SDL. The fourth driving voltage line VDL4 may electrically connect the third driving voltage lines VDL3 disposed on the upper and lower sides of the non-display area NDA.

The reference voltage line VRL may include the first to fourth reference voltage lines VRL1, VRL2, VRL3, and VRL4. In FIGS. 5 and 8, the first reference voltage line VRL1 may extend from the source metal layer SDL in the second direction DR2. The first reference voltage line VRL1 may extend from the lower side of the non-display area NDA to the upper side of the display area DA. The first reference voltage line VRL1 may supply the reference voltage Vref received from the flexible film FPCB to the display area DA. The first reference voltage line VRL1 may overlap the fan out line FOL on the lower side of the non-display area NDA and intersect the third driving voltage line VDL3, the third reference voltage line VRL3, and the first low-potential line VSL1. The first reference voltage line VRL1 may intersect the second driving voltage line VDL2 and the second reference voltage line VRL2 in the display area DA. The first reference voltage line VRL1 may intersect the third reference voltage line VRL3 on the upper side of the non-display area NDA.

In FIGS. 5 and 7, the second reference voltage line VRL2 may extend from the first light-blocking layer LS1 in the first direction DR1. The second reference voltage line VRL2 may extend from the left side to the right side of the display area DA. The second reference voltage line VRL2 may be connected to the first reference voltage line VRL1 to receive the reference voltage Vref and supply the reference voltage Vref to the pixel PX.

In FIGS. 5 and 8, the third reference voltage line VRL3 may extend from the gate layer GTL in the first direction DR1. The third reference voltage line VRL3 may be disposed on each of the upper and lower sides of the non-display area NDA. The third reference voltage line VRL3 may intersect the fan out line FOL, the first driving voltage line VDL1, the first reference voltage line VRL1, and the initialization voltage line VIL on the lower side of the non-display area NDA. The third reference voltage line VRL3 may be connected to the first reference voltage line VRL1 to receive the reference voltage Vref and supply the reference voltage Vref to the fourth reference voltage line VRL4.

The fourth reference voltage line VRL4 may extend from each of the left and right sides of the non-display area NDA in the second direction DR2. The fourth reference voltage line VRL4 may be disposed between the gate driver 300 and the display area DA. Although not illustrated, the fourth reference voltage line VRL4 may be disposed on the source metal layer SDL. The fourth reference voltage line VRL4 may electrically connect the third reference voltage lines VRL3 disposed on the upper and lower sides of the non-display area NDA.

In FIGS. 5 and 8, the initialization voltage line VIL may extend from the source metal layer SDL in the second direction DR2. The initialization voltage line VIL may extend from the lower side of the non-display area NDA to the upper side of the display area DA. The initialization voltage line VIL may supply the initialization voltage Vint received from the flexible film FPCB to the display area DA. The initialization voltage line VIL may overlap the fan out line FOL on the lower side of the non-display area NDA and intersect the third driving voltage line VDL3, the third reference voltage line VRL3, and the first low-potential line VSL1. The initialization voltage line VIL may intersect the second driving voltage line VDL2 and the second reference voltage line VRL2 in the display area DA.

The low-potential line VSL may include first and second low-potential lines VSL1 and VSL2. Although not illustrated, the first low-potential line VSL1 may extend from the gate layer GTL in the first direction DR1. The first low-potential line VSL1 may be disposed on each of the upper and lower sides of the non-display area NDA. The first low-potential line VSL1 may intersect the fan out line FOL, the first driving voltage line VDL1, the first reference voltage line VRL1, and the initialization voltage line VIL on the lower side of the non-display area NDA.

The second low-potential line VSL2 may extend from each of the left and right sides of the non-display area NDA in the second direction DR2. The second low-potential line VSL2 may be disposed outside the gate driver 300. Although not illustrated, the second low-potential line VSL2 may be disposed in the source metal layer SDL. The second low-potential line VSL2 may electrically connect the first low-potential lines VSL1 disposed on the upper and lower sides of the non-display area NDA.

In FIG. 6, the flexible film FPCB may include a lead electrode LDE. The lead electrode LDE of the flexible film FPCB may be electrically connected to a pad part PAD through a connection film ACF. The pad part PAD may be disposed in the first light-blocking layer LS1 in the second pad area PA2 illustrated in FIG. 2. The flexible film FPCB may supply signals and voltages received from the controller 200, the power supply unit 500, and the host system to the display panel 100. The pad part PAD may be in contact with the initialization voltage line VIL inserted into a contact hole passing through the first protective layer PLN1, the interlayer insulating layer ILD, the gate insulating layer GI, the second buffer layer BF2, and the first buffer layer BF1.

In FIG. 7, the scan line SCL may extend from the first light-blocking layer LS1 in the first direction DR1. The scan line SCL may be the first scan line SCL1 or the second scan line SCL2 illustrated in FIG. 3.

The light-emitting control line EML may extend from the first light-blocking layer LS1 in the first direction DR1. The light-emitting control line EML may be the first light-emitting control line EML1 or the second light-emitting control line EML2 illustrated in FIG. 3.

In FIG. 8, the fan out line FOL may be disposed in the first light-blocking layer LS1. The fan out line FOL may supply the data voltage received from the data driver 400 to the data line DL of the display area DA.

FIGS. 9 to 13 are cross-sectional views of a manufacturing process of the display device according to one embodiment.

In FIG. 9, the substrate SUB may be a base substrate or a base member. The substrate SUB may include at least one plastic material. For example, the substrate SUB may be a multi-substrate including a plurality of plastic materials, such as polyimide, but a constituent material of the substrate SUB is not limited thereto.

The first light-blocking layer LS1 may be disposed on the substrate SUB. The first light-blocking layer LS1 may include the first capacitor electrode CPE1 of the first capacitor C1 and the first scan line SCL1. The first light-blocking layer LS1 may be formed of a single layer or multiple layers formed of one of molybdenum (Mo), aluminum (Al), chromium (Cr), gold (Au), titanium (Ti), nickel (Ni), neodymium (Nd), and copper (Cu), or an alloy thereof, but is not limited thereto.

The first buffer layer BF1 may be disposed on the first light-blocking layer LS1. The first buffer layer BF1 may include an inorganic film capable of preventing the penetration of air or moisture. For example, the first buffer layer BF1 may include a plurality of inorganic films alternately stacked.

The second light-blocking layer LS2 may be disposed on the first buffer layer BF1. The second light-blocking layer LS2 may include the second capacitor electrode CPE2 of the first capacitor C1. The second capacitor electrode CPE2 may overlap the first capacitor electrode CPE1 to form the first capacitor C1. The second light-blocking layer LS2 may include a material exemplified in the first light-blocking layer LS1, but is not limited thereto.

The second buffer layer BF2 may be disposed on the second light-blocking layer LS2. The second buffer layer BF2 may include an inorganic film capable of preventing the penetration of air or moisture. For example, the second buffer layer BF2 may include a plurality of inorganic films alternately stacked.

The active layer ACTL may be disposed on the second buffer layer BF2. The active layer ACTL may include an oxide-based material, but is not limited thereto. The active layer ACTL may include the semiconductor area ACT1, the drain electrode DE1, the source electrode SEI of the first transistor T1, and the semiconductor area ACT5, the drain electrode DE5, and the source electrode SE5 of the fifth transistor T5.

The gate insulating layer GI may be disposed on the active layer ACTL. The gate insulating layer GI may insulate an active layer ACTL1 and the gate layer GTL.

The gate layer GTL may be disposed on the gate insulating layer GI. The gate layer GTL may include the gate electrode GE1 of the first transistor T1 and the gate electrode GE5 of the fifth transistor T5.

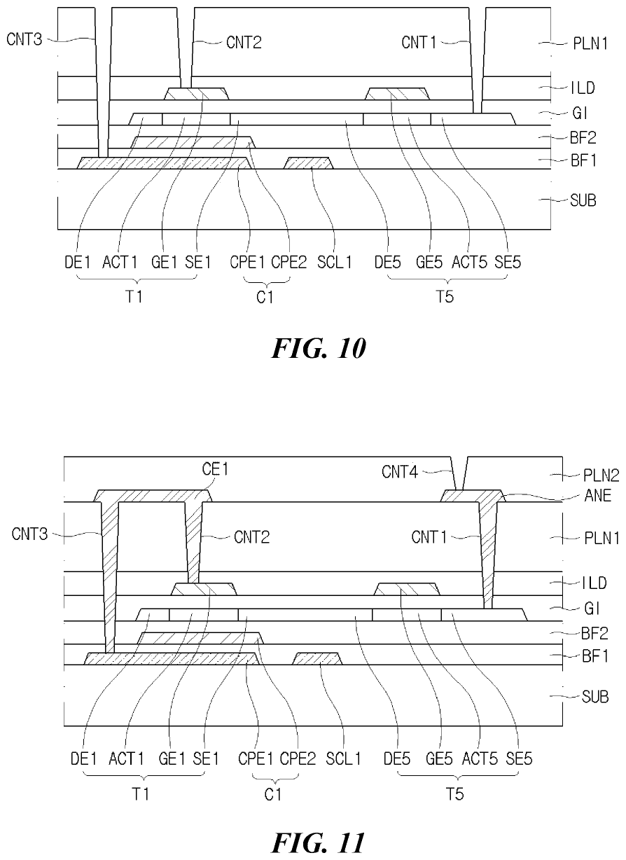

In FIG. 10, the interlayer insulating layer ILD may be disposed on the gate layer GTL. The interlayer insulating layer ILD may insulate the gate layer GTL and the source metal layer SDL.

The first protective layer PLN1 may be disposed on the interlayer insulating layer ILD. The first protective layer PLN1 may planarize the upper portions of the transistors and protect the transistors. The first protective layer PLN1 may include an organic material. For example, the first protective layer PLN1 may include an acrylic resin, an epoxy resin, a phenolic resin, a polyamide resin, or a polyimide resin, but is not limited thereto.

The first contact hole CNT1 may be etched from an upper surface of the first protective layer PLN1 and may pass through a lower surface of the gate insulating layer GI. The first contact hole CNT1 may expose a part of an upper surface of the source electrode SE5 of the fifth transistor T5.

The second contact hole CNT2 may be etched from the upper surface of the first protective layer PLN1 and may pass through a lower surface of the interlayer insulating layer ILD. The second contact hole CNT2 may expose a part of an upper surface of the gate electrode GE1 of the first transistor T1.

The third contact hole CNT3 may be etched from the upper surface of the first protective layer PLN1 and may pass through the lower surface of the first buffer layer BF1. The third contact hole CNT3 may expose a part of an upper surface of the first capacitor electrode CPE1.

The upper surface of the first protective layer PLN1 may be etched through at least one of a dry etching process, a plasma etching process, and a laser etching process. The first to third contact holes CNT1, CNT2, and CNT3 may be formed using one mask formed on the first protective layer PLN1. Accordingly, the display device 10 may include only one source metal layer SDL between the transistors of the pixel circuit and the pixel electrode AE of the light-emitting element ED, thereby reducing the number of masks in the manufacturing process and the manufacturing cost. The display device 10 may reduce the number of conductive layers, thereby optimizing the process and shortening the manufacturing period.

In FIG. 11, the source metal layer SDL may be disposed on the first protective layer PLN1. The source metal layer SDL may include the first connection electrode CE1 and the anode connection electrode ANE. The first connection electrode CE1 may electrically connect the gate electrode GE1 of the first transistor T1 and the first capacitor electrode CPE1 of the first capacitor C1. The first connection electrode CE1 may be inserted into the second contact hole CNT2 to be in contact with the gate electrode GE1 of the first transistor T1. The first connection electrode CE1 may be inserted into the third contact hole CNT3 to be in contact with the first capacitor electrode CPE1.

The anode connection electrode ANE may electrically connect the source electrode SE5 of the fifth transistor T5 to the pixel electrode AE. The anode connection electrode ANE may be inserted into the first contact hole CNT1 to be in contact with the gate electrode SE5 of the first transistor T5.

The second protective layer PLN2 may be disposed on the source metal layer SDL. The second protective layer PLN2 may planarize the upper portion of the source metal layer SDL and protect the source metal layer SDL. The second protective layer PLN2 may include an organic material. For example, the second protective layer PLN2 may include the material exemplified in the first protective layer PLN1, but is not limited thereto.

A fourth contact hole CNT4 may be etched from an upper surface of the second protective layer PLN2 and may pass through a lower surface of the second buffer layer PLN2. The fourth contact hole CNT4 may expose a part of an upper surface of the anode connection electrode ANE.

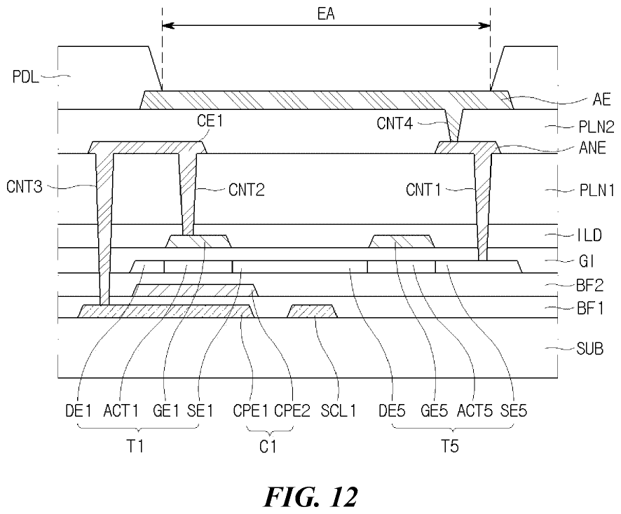

In FIG. 12, the pixel electrode AE may be disposed on the second protective layer PLN2. The pixel electrode AE may be inserted into the fourth contact hole CNT4 to be in contact with the anode connection electrode ANE.

The pixel defining layer PDL may be disposed on the second protective layer PLN2. The pixel defining layer PDL may define the light-emitting area EA or the opening area. The light-emitting area EA may be disposed on an upper surface of the pixel electrode AE. The pixel defining layer PDL may include a material including a black pigment, etc., an organic material, such as a benzocyclobutene resin, a polyimide resin, an acrylic resin, a photosensitive polymer, etc., but is not limited thereto. When the pixel defining layer PDL includes a material including a black pigment, a black dye, etc., the pixel defining layer PDL may be a black bank. The pixel defining layer PDL may include a black pigment or a black dye, thereby blocking external light and increasing the luminance of the display device 10.

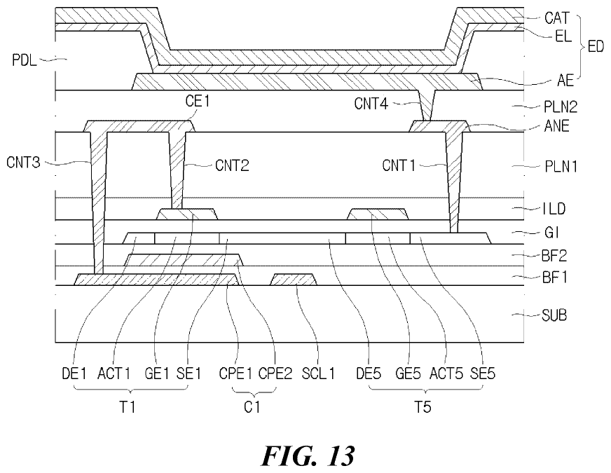

In FIG. 13, the light-emitting layer EL may be disposed on the pixel electrode AE. For example, the light-emitting layer EL may be an organic light-emitting layer formed of an organic material, but is not limited thereto.

The common electrode CAT may be disposed on the light-emitting layer EL. For example, the common electrode CAT may be implemented in the form of an electrode that is common to all pixels PX without being distinguished by each pixel PX. The common electrode CAT may be a transparent electrode and may transmit light. The common electrode CAT may be electrically connected to the low-potential line VSL and may receive a low-potential voltage, a common voltage, or a cathode voltage.

The display device 10 according to various embodiments of the present specification may be described as follows.

According to various embodiments of the present specification, there is provided a display device including a substrate including a display area and a non-display area surrounding the display area, a first light-blocking layer disposed on the substrate, an active layer including a semiconductor area of a first transistor disposed on the first light-blocking layer, a gate layer including a gate electrode of the first transistor disposed on the active layer, a source metal layer disposed on the gate layer and including an anode connection electrode that is directly connected to the active layer and receives a driving current flowing in the first transistor, a pixel electrode disposed on the source metal layer and directly connected to the anode connection electrode, a light-emitting layer disposed on the pixel electrode, and a common electrode disposed on the light-emitting layer.

The display device according to various embodiments of the present specification may further include a second light-blocking layer disposed between the first light-blocking layer and the active layer, and a first capacitor formed between the gate electrode of the first transistor and a source electrode of the first transistor, wherein the first capacitor may include a first capacitor electrode disposed in the first light-blocking layer and electrically connected to the gate electrode of the first transistor, and a second capacitor electrode disposed in the second light-blocking layer and electrically connected to the source electrode of the first transistor.

In the display device according to various embodiments of the present specification, the first and second capacitor electrodes may overlap a semiconductor area of the first transistor.

The display device according to various embodiments of the present specification may further include a first scan line disposed in the first light-blocking layer and supplying a first scan signal, and a second transistor supplying a data voltage to the gate electrode of the first transistor based on the first scan signal.

The display device according to various embodiments of the present specification may further include a third transistor supplying a reference voltage to the gate electrode of the first transistor based on a second scan signal, a fourth transistor supplying a driving voltage to the drain electrode of the first transistor based on a first light-emitting signal, and a fifth transistor electrically connecting the source electrode of the first transistor to the pixel electrode based on a second light-emitting signal.

The display device according to various embodiments of the present specification may further include a sixth transistor supplying an initialization voltage to the pixel electrode of the light-emitting element based on a third scan signal.

In the display device according to various embodiments of the present specification, the source metal layer may further include a first connection electrode electrically connecting the gate electrode of the first transistor to the first capacitor electrode.

The display device according to various embodiments of the present specification may further include a flexible film disposed on a first side of the non-display area, and a pad part disposed in the first light-blocking layer and electrically connected to the flexible film.

The display device according to various embodiments of the present specification may further include a first driving voltage line disposed in the source metal layer and extending from a first side of the non-display area to a second side opposite to the first side of the non-display area in a first direction, a second driving voltage line disposed in the first light-blocking layer and extending in a second direction intersecting the first direction in the display area, and third driving voltage lines disposed in the gate layer and extending from the first side and the second side of the non-display area in the second direction.

The display device according to various embodiments of the present specification may further include a data driver disposed between the flexible film and the display area and supplying a data voltage, and a fan out line disposed in the first light-blocking layer, extending from the data driver to the display area, and overlapping the first driving voltage line and the third driving voltage line.

The display device according to various embodiments of the present specification may further include first low-potential lines disposed in the gate layer and extending from the first side and the second side of the non-display area in the first direction, and a second low-potential line disposed in the source metal layer and extending from a third side adjacent to the first side of the non-display area in the second direction to electrically connect the first low-potential lines.

The display device according to various embodiments of the present specification may further include a fourth driving voltage line disposed in the source metal layer and extending from the third side of the non-display area in the second direction to electrically connect the third driving voltage lines, and a gate driver disposed between the fourth driving voltage line and the second low-potential line and supplying a gate signal.

According to various embodiments of the present specification, there is provided a display device including a substrate including a display area and a non-display area surrounding the display area, a light-emitting element including a pixel electrode and emits light, a first transistor supplying a driving current to the pixel electrode, an active layer disposed on the substrate and including a semiconductor area of the first transistor, a second transistor supplying the data voltage to a gate electrode of the first transistor based on a first scan signal, a third transistor supplying a reference voltage to the gate electrode of the first transistor based on a second scan signal, a fourth transistor supplying a driving voltage to a drain electrode of the first transistor based on a first light-emitting signal, a fifth transistor including a drain electrode and a source electrode disposed in the active layer and electrically connecting the source electrode of the first transistor to the pixel electrode based on a second light-emitting signal, and an anode connection electrode directly connecting the source electrode of the fifth transistor to the pixel electrode.

The display device according to various embodiments of the present specification may further include a first light-blocking layer disposed between the substrate and the active layer, a gate layer including the gate electrode of the first transistor disposed on the active layer, and a source metal layer disposed on the gate layer and including the anode connection electrode.

The display device according to various embodiments of the present specification may further include a second light-blocking layer disposed in a layer between the first light-blocking layer and the active layer, and a first capacitor including a first capacitor electrode disposed in the first light-blocking layer and electrically connected to the gate electrode of the first transistor, and a second capacitor electrode disposed in the second light-blocking layer and electrically connected to the source electrode of the first transistor.

In the display device according to various embodiments of the present specification, the source metal layer may further include a first connection electrode electrically connecting the gate electrode of the first transistor to the first capacitor electrode.

The display device according to various embodiments of the present specification may further include a first scan line disposed in the first light-blocking layer and supplying the first scan signal to a gate electrode of the second transistor, and a second scan line disposed in the first light-blocking layer and supplying the second scan signal to a gate electrode of the third transistor.

The display device according to various embodiments of the present specification may further include a flexible film disposed on one side of the substrate, and a pad part disposed in the first light-blocking layer and electrically connected to the flexible film.

The display device according to various embodiments of the present specification may further include a first driving voltage line disposed in the source metal layer and extending from a first side of the non-display area adjacent to the flexible film, the display area, and a second side opposite to the first side of the non-display area in a first direction, a second driving voltage line disposed in the first light-blocking layer and extending in a second direction intersecting the first direction in the display area, and third driving voltage lines disposed in the gate layer and extending from the first side and the second side of the non-display area in the second direction.

The display device according to various embodiments of the present specification may further include a data driver disposed between the flexible film and the display area and supplying a data voltage, and a fan out line disposed in the first light-blocking layer, extending from the data driver to the display area, and overlapping the first driving voltage line and the third driving voltage line.

In the display device according to the embodiments of the present specification, by including only one source metal layer between transistors of the pixel circuit and the pixel electrode of the light-emitting element, it is possible to reduce the number of masks of the manufacturing process and reduce the manufacturing cost.

In the display device according to the embodiments of the present specification, it is possible to optimize the process by reducing the number of conductive layers.

However, effects obtainable from the present specification are not limited to the above-described effects, and other effects that are not mentioned will be able to be clearly understood by those skilled in the art to which the present specification pertains based on the following description.

Although one embodiment has been described above with reference to the accompanying drawings, those skilled in the art to which the specification pertains will be able to understand that the above-described technical configuration of the present disclosure can be carried out in other specific forms without changing the technical spirit or essential features thereof. Accordingly, it should be understood that the above-described embodiments are illustrative and not restrictive in all respects. In addition, the scope of the specification is described by the claims to be described below rather than the detailed description. In addition, the meaning and scope of the claims and all changed or modified forms derived from the equivalent concept should be construed as being included in the scope of the specification.

### DESCRIPTION OF REFERENCE NUMERALS

10: display device
100: display panel
200: controller
300: gate driver
400: data driver
500: power supply unit
LS1: first light-blocking layer
LS2: second light-blocking layer
ACTL: active layer
GTL: gate layer
SDL: source metal layer
ED: light-emitting element

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a substrate including a display area and a non-display area adjacent to the display area;
a first light-blocking layer on the substrate;
a first transistor on the first light-blocking layer, the first transistor including a semiconductor area, a source electrode, a drain electrode, and a gate electrode;
an active layer including the semiconductor area of the first transistor;
a gate layer including the gate electrode of the first transistor on the active layer;
a source metal layer on the gate layer and including an anode connection electrode that is directly connected to the active layer and receives a driving current from the first transistor;
a pixel electrode on the source metal layer and directly connected to the anode connection electrode;
a light-emitting layer on the pixel electrode; and
a common electrode on the light-emitting layer.

2. The display device of claim 1, further comprising:
a second light-blocking layer between the first light-blocking layer and the active layer; and
a first capacitor between the gate electrode of the first transistor and the source electrode of the first transistor,
wherein the first capacitor includes:
a first capacitor electrode disposed in the first light-blocking layer and electrically connected to the gate electrode of the first transistor; and
a second capacitor electrode disposed in the second light-blocking layer and electrically connected to the source electrode of the first transistor.

3. The display device of claim 2, wherein the first and second capacitor electrodes overlap the semiconductor area of the first transistor.

4. The display device of claim 2, further comprising:
a first scan line disposed in the first light-blocking layer and supplying a first scan signal; and
a second transistor supplying a data voltage to the gate electrode of the first transistor based on the first scan signal.

5. The display device of claim 4, further comprising:
a third transistor supplying a reference voltage to the gate electrode of the first transistor based on a second scan signal;
a fourth transistor supplying a driving voltage to the drain electrode of the first transistor based on a first light-emitting signal; and
a fifth transistor electrically connecting the source electrode of the first transistor to the pixel electrode based on a second light-emitting signal.

6. The display device of claim 5, further comprising a sixth transistor supplying an initialization voltage to the pixel electrode of the light-emitting element based on a third scan signal.

7. The display device of claim 2, wherein the source metal layer further includes a first connection electrode electrically connecting the gate electrode of the first transistor to the first capacitor electrode.

8. The display device of claim 1, further comprising:
a flexible film on one side of the substrate; and
a pad part disposed in the first light-blocking layer and electrically connected to the flexible film.

9. The display device of claim 8, further comprising:
a first driving voltage line disposed in the source metal layer and extending from a first side of the non-display area adjacent to the flexible film, the display area, and a second side opposite to the first side of the non-display area in a first direction;
a second driving voltage line disposed in the first light-blocking layer and extending in a second direction intersecting the first direction in the display area; and
third driving voltage lines disposed in the gate layer and extending from the first side and the second side of the non-display area in the second direction.

10. The display device of claim 9, further comprising:
a data driver between the flexible film and the display area and supplying a data voltage; and
a fan out line disposed in the first light-blocking layer, extending from the data driver to the display area, and overlapping the first driving voltage line and the third driving voltage line.

11. The display device of claim 9, further comprising:
first low-potential lines disposed in the gate layer and extending from the first side and the second side of the non-display area in the first direction; and
a second low-potential line disposed in the source metal layer and extending from a third side adjacent to the first side of the non-display area in the second direction to electrically connect the first low-potential lines.

12. The display device of claim 11, further comprising:
a fourth driving voltage line disposed in the source metal layer and extending from the third side of the non-display area in the second direction to electrically connect the third driving voltage lines; and
a gate driver between the fourth driving voltage line and the second low-potential line and supplying a gate signal.

13. A display device comprising:
a substrate including a display area and a non-display area adjacent to the display area;
a light-emitting element including a pixel electrode and emits light;
a first transistor supplying a driving current to the pixel electrode;
an active layer on the substrate and including a semiconductor area of the first transistor;
a second transistor supplying the data voltage to a gate electrode of the first transistor based on a first scan signal;
a third transistor supplying a reference voltage to the gate electrode of the first transistor based on a second scan signal;
a fourth transistor supplying a driving voltage to a drain electrode of the first transistor based on a first light-emitting signal;
a fifth transistor including a drain electrode and a source electrode disposed in the active layer and electrically connecting the source electrode of the first transistor to the pixel electrode based on a second light-emitting signal; and
an anode connection electrode directly connecting the source electrode of the fifth transistor to the pixel electrode.

14. The display device of claim 13, further comprising:
a first light-blocking layer between the substrate and the active layer;
a gate layer including a gate electrode of the first transistor on the active layer; and
a source metal layer on the gate layer and including the anode connection electrode.

15. The display device of claim 14, further comprising:
a second light-blocking layer between the first light-blocking layer and the active layer; and
a first capacitor including a first capacitor electrode disposed in the first light-blocking layer and electrically connected to the gate electrode of the first transistor, and a second capacitor electrode disposed in the second light-blocking layer and electrically connected to the source electrode of the first transistor.

16. The display device of claim 15, wherein the source metal layer further includes a first connection electrode electrically connecting the gate electrode of the first transistor to the first capacitor electrode.

17. The display device of claim 14, further comprising:
a first scan line disposed in the first light-blocking layer and supplying the first scan signal to a gate electrode of the second transistor; and
a second scan line disposed in the first light-blocking layer and supplying the second scan signal to a gate electrode of the third transistor.

18. The display device of claim 14, further comprising:
a flexible film on one side of the substrate; and
a pad part disposed in the first light-blocking layer and electrically connected to the flexible film.

19. The display device of claim 18, further comprising:
a first driving voltage line disposed in the source metal layer and extending from a first side of the non-display area adjacent to the flexible film, the display area, and a second side opposite to the first side of the non-display area in a first direction;
a second driving voltage line disposed in the first light-blocking layer and extending in a second direction intersecting the first direction in the display area; and
third driving voltage lines disposed in the gate layer and extending from the first side and the second side of the non-display area in the second direction.

20. The display device of claim 19, further comprising:
a data driver between the flexible film and the display area and supplying a data voltage; and
a fan out line disposed in the first light-blocking layer, extending from the data driver to the display area, and overlapping the first driving voltage line and the third driving voltage line.
